(19) United States
(12) Patent Application Publication
(10) Pub. No.: US 2020/0315376 A1
(43) Pub. Date: Oct. 8, 2020

(54) ELECTRONIC KIOSK SYSTEM, SUPPORTING COLUMN AND USE OF A HOLLOW PROFILE

(71) Applicant: Pyramid Computer GmbH, Freiburg (DE)

(72) Inventor: Peter Hermann ENGLER, Emmendingen (DE)

(73) Assignee: Pyramid Computer GmbH, Freiburg (DE)

(21) Appl. No.: 16/837,409

(22) Filed: Apr. 1, 2020

(30) Foreign Application Priority Data
Apr. 4, 2019 (DE) 102019108865.8

(51) Int. Cl. A47F 9/04; A47F 3/04; A47F 3/00; G06F 1/20; G06F 1/18; H05K 7/20; H05K 7/14

(52) U.S. Cl. CPC A47F 9/04; A47F 3/0408; A47F 3/002; H05K 7/14; G06F 1/20; G06F 1/181; H05K 7/20136; A47F 3/001

(57) ABSTRACT

An electronic kiosk system (1) including at least one supporting column (2) which has a cavity in which at least one storage compartment is formed with one insertion opening, wherein at least one processor unit is inserted into the at least one storage compartment. At least one input and/or output module (3, 15, 36) is arranged on an outer side (4) of a wall (5) of the supporting column and is held thereby. The wall has at least one breakthrough (6) which leads from the inside to the outside and by which an interface (7) is formed between the processor unit and the at least one input and/or output module, as a result of which at least one self-service terminal (8, 17, 38) is formed. In addition, a supporting column, the use of a hollow profile (14) and to a kit for producing an electronic kiosk system (1) are provided.

### INCORPORATION BY REFERENCE

The following documents are incorporated herein by reference as if fully set forth: German Patent Application No. DE 102019108865.8, filed Apr. 4, 2019.

### TECHNICAL FIELD

The invention relates to an electronic kiosk system.

Furthermore, the invention relates to a supporting column.

Finally, the invention relates to the use of a hollow profile for producing a supporting column.

### BACKGROUND

Kiosk systems are interactive computer installations which are usually installed in a public space or at semi-public locations such as in supermarkets, leisure parks or at railroad stations, so that by operating said systems a user is provided with the possibility of, for example, obtaining desired information, buying or ordering an entry card or goods, surfing on the Internet or independently executing a retail service transaction such as finding and paying for goods in a supermarket, without the need for help from staff.

Kiosk systems which are embodied as self-service terminals are already known in this context, wherein these kiosk systems generally have a housing in which a touch-sensitive screen (touchscreen) is arranged as a display and input unit. Sometimes the kiosk systems have other output units which are arranged in the housing, such as for example a printer or a scanner, so that a user can execute additional actions.

However, previously known kiosk systems have the disadvantage that they require a relatively large amount of space but only one user can operate the kiosk system at any one time. This results in a situation in which long lines can form at previously known kiosk systems if a large number of users wish to use the kiosk system at the same time.

There is therefore the problem of making available an electronic kiosk system which has properties of use which are improved in comparison with previously known electronic kiosk systems.

### SUMMARY

This problem is solved by an electronic kiosk system having one or more features according to the invention.

In particular, in order to solve the problem the invention provides an electronic kiosk system comprising at least one supporting column which has at least one storage compartment with one insertion opening, wherein at least one processor unit is inserted into the at least one storage compartment, and at least one input and/or output module which is arranged on an outer side of a wall of the supporting column and is held by the supporting column, wherein a wall of the supporting column has at least one breakthrough which leads outward and on which an interface is arranged, via which interface the processor unit is electrically coupled to the at least one input and/or output module, as a result of which at least one self-service terminal is formed. Therefore, in comparison with previously known electronic kiosk systems it is possible to reduce the space required for the installation of the kiosk system according to the invention to a minimum, since an input and/or output module of the kiosk system is no longer installed in a wide housing, as it was in the past, but rather is mounted on a significantly narrower supporting column. In previous kiosk systems it has been customary for a width of the housing to be determined by a width of the display unit which is usually configured as a touch-sensitive screen. The invention here adopts a different approach, since the at least one input and/or output module is arranged outside the supporting column, which at the same time assumes a function as a computer housing. Moreover, the variation possibilities in respect of the arrangement of the at least one input and/or output module on the supporting column are virtually unlimited with the electronic system according to the invention, since the position of the at least one input and/or output module on the outer side of the wall of the supporting column can be freely selected. It is therefore possible, for example, to virtually freely select a height of the input and/or output module and/or an angle at which the at least one input and/or output module projects from the supporting column. In addition, a number of input and/or output modules which are mounted on the supporting column can also be easily adapted to the requirements of the respective arrangement. It can be particularly advantageous if the at least one input and/or output module has a housing, in particular a watertight housing.

Advantageous refinements of the invention, which can be implemented alone or optionally in combination with one or more of the features and other refinements noted above, are described below.

According to one advantageous embodiment, there can be provision that arranged in the supporting column is a central cooler device through which cooling air can be sucked in from the outside into the supporting column via an inlet point and an air flow via an air flow duct, formed by the supporting column, past the at least one processor unit to an outlet point can be set. In this context, the air flow duct can run from a first end of the supporting column to a second end of the supporting column. The central cooler device can therefore conduct the cooling air unidirectionally through the air flow duct, in particular past the at least one processor unit. Therefore, particularly good cooling of the at least one processor unit can be ensured in that the waste heat which is produced thereby is carried away by the cooling air flowing through the air flow duct.

According to a further advantageous embodiment there can be provision that the supporting column is embodied in one part, in particular monolithically. According to one particularly advantageous refinement, the supporting column can be produced at least partially from a hollow profile, preferably from an extruded hollow profile. This has the advantage that particularly cost-effective production is possible of a sufficiently solid and stable supporting column which satisfies particularly well the functions as a housing for the electronic components and as a stand unit for input and/or output modules which are arranged on the outer side of said components.

In order to expand the functionality of the electronic kiosk system, the electronic kiosk system can have at least two input and/or output modules which are arranged offset with respect to one another in the circumferential direction and/or in the longitudinal direction of the supporting column on the outer side of the wall, and are held by the supporting column. The kiosk system therefore has the advantage that a plurality of actions can therefore also be carried out in a relatively small space on a supporting column. In this context there may be provision that a separate breakthrough and a separate interface for connecting to a processor unit are formed for each of the input modules and/or output modules. Therefore, the supporting column does not have more openings and/or breakthroughs than are necessary. This simplifies, in particular, the sealing of the supporting column if it is provided to be installed in an external area.

In order to permit simultaneous use of the electronic kiosk system by a plurality of users at the same time, the electronic kiosk system can have two or more processor units which are arranged in storage compartments which are arranged offset with respect to one another in the longitudinal direction (direction of extent) of the supporting column, in particular one after the other, wherein each processor unit is coupled to at least one input and/or output module and forms an independent self-service terminal. Every self-service terminal can be operated by a user. The storage compartments are embodied offset with respect to one another here in the longitudinal direction of the supporting column so that each storage compartment lies at least partially in the air flow duct in a space-saving fashion. The serial arrangement and/or stackwise arrangement of the plurality of processor units within the supporting column permits, on the one hand, that a width and a depth of the supporting column can remain unchanged with respect to a kiosk system with just one processor unit. More space is necessary only in the height, which, however, is not significant insofar as the supporting column nevertheless has to have a certain minimum height owing to its function as a stand unit for the at least one input and/or output module. This has the advantage that the supporting column can be of the same design irrespective of the number of self-service terminals which are arranged thereon. Furthermore, this type of arrangement has the advantage that a sufficient and uniform cooling of the processor units is achieved. Each processor unit can be embodied as a main circuit board. This circuit board can have individual components such as a processor, RAM memory, BIOS chip, graphics card, peripheral connections and other expansion cards.

The electronic kiosk system can be configured for a multiplicity of fields of application by using different input and/or output modules. According to the application, input and/or output modules can be understood to be all devices which serve to input information or a command and/or to output, in particular to display, information. A number of examples of possible input and/or output modules are listed here below, wherein this list is not to be considered exhaustive. Therefore there may be provision that the at least one input and/or output module is embodied as a module or as a plurality of modules selected from the group composed of a display, touchscreen, balance, payment module, card reader, scanner, sensor module, printer, camera, goods output module, goods return module, shelf module, storage module. In this way, the electronic kiosk system - and in particular also the kit which is described in more detail below - can cover a large number of different fields of application without wide ranging redesign of the kiosk system being necessary here, as is the case in previous kiosk systems.

According to one particularly advantageous refinement of the electronic kiosk system, the at least one self-service terminal or all the self-service terminals can have at least one input and/or output module which is/are embodied as a display, in particular as a touchscreen, and optionally a further input and/or output module. With most applications of an electronic kiosk system it is necessary for the user to be provided with information, which can be done by the display.

A refinement of the electronic kiosk system which is particularly economical in terms of current and in addition also produces less waste heat can have a central power supply unit, by which the at least one processor unit or all the processor units is/are supplied with current during operation. In addition, as a result, the space required can be reduced further, since fewer components would be necessary if each processor unit were to have its own power supply unit. The power supply unit here can preferably be arranged at least partially within the air flow duct, so that the latter can also be cooled by the through-flowing cooling air.

In order to be able to prevent undesired access to the processor units and to the further components of the kiosk system, which are arranged in the interior of the supporting column, the insertion opening of the storage compartment or the insertion openings of the storage compartments can be covered in the position of use by a cover device. The cover device can preferably be fixedly connected to the supporting column by a latch connection. Moreover, the cover device can have a closing apparatus which permits the cover device to close, so that in the closed state said cover device cannot be removed from the supporting column.

As already explained above, the components of the electronic kiosk system are to be arranged so as to save as much space as possible in order to be able to make the supporting column as narrow as possible. Therefore, according to a further advantageous refinement there may be provision that a width of the supporting column and/or a width of an air flow duct, for example of the air flow duct already mentioned above, are/is determined by a width of the at least one storage compartment and/or a space requirement of the at least one processor unit. Customarily, a maximum width of the housings of previously known kiosk systems has previously been determined by a width of the installed display devices. In the case of the kiosk system such as is described and claimed here, the external dimensions of the supporting column are, on the other hand, not determined by the display and/or some other input and/or output module. Therefore, the arrangement and orientation of said supporting column is significantly more flexible, so that overall significantly less space is necessary.

According to a further advantageous refinement which has already been indicated above, the processor unit or all the processor units can be embodied without a separate power supply unit.

Alternatively or additionally to this, it may be advantageous to bring about even better cooling of the processor unit/units by virtue of the fact that the at least one processor unit or all the processor units has/have one local cooler unit each.

In order to be able to avoid a situation in which the discharge air of the electronic kiosk system is output into the surrounding space, according to a further advantageous refinement an outlet point, for example the outlet point which has already been mentioned above, of the air flow duct can be or is connected to a ventilation system of a ventilation installation via a connecting line.

In order to make additional information which is to be displayed available, for example, to the users of the kiosk system independently of the individual self-service terminal, the electronic kiosk system can have a display device and/or lighting device. The display and/or lighting device can be controllable here by a display and/or lighting control circuit board or can be controlled during operation. This has the advantage that general additional information can be displayed to the users and/or that attention is drawn to the kiosk system by a lighting system in order to make the kiosk system easier to find.

Since the electronic kiosk system can be positioned in a public space, it may be the case that users lean against it or pull themselves up on it. In order to better prevent the supporting column from tipping over, the electronic kiosk system can have a supporting foot of which the footprint is larger than a cross-sectional area of the supporting column. Alternatively or additionally to this, the electronic kiosk system can be capable of being mounted or be mounted in a positionally fixed fashion on the ground by a securing device or in a positionally fixed fashion in the position of use. Therefore, a particularly stable stand of the kiosk system can be formed, wherein the kiosk system is also prevented from being able to be carried away. The securing device can be installed on the floor, for example by screwing the supporting column.

The abovementioned problem is also solved by a supporting column having one or more of the features provided herein.

In particular, in order to solve the abovementioned problem a supporting column is proposed which has a hollow profile as a base body, wherein a wall of the base body has at least one insertion opening into a storage component in the interior of the base body and at least one breakthrough into the storage compartment for setting up an interface, and wherein an air flow duct which is bounded by the wall of the base body is formed in the interior of the base body. As has already been described above with respect to the electronic kiosk system, the supporting column has the advantage that the individual components of the kiosk system can be arranged or are arranged in a particularly space-saving fashion by virtue of their use. Therefore, the described and claimed supporting column is particularly suitable for producing an electronic kiosk system such as has been described and claimed herein. An extruded hollow profile can preferably be used as the hollow profile, as a result of which it is possible to produce a particularly solid and stable supporting column which is suitable for relatively long use in a public space. In addition, the production of an extruded hollow profile is relatively cost-effective. The supporting column can therefore be embodied in one part, in particular monolithically.

In addition, the abovementioned problem can be solved by the use of a hollow profile for producing a supporting column according to one or more of the features described herein.

An extruded hollow profile can preferably also be used here. In particular, a supporting column such as is described and claimed herein, and/or an electronic kiosk system such as is described and claimed herein, can be produced therewith. In this context there may be provision that the hollow profile is used as a housing for accommodating computer components in order to protect them against external influences, as an air duct for cooling the computer components and as a stand element for at least one input and/or output module which is arranged on an outer side of the hollow profile. Therefore, a particularly space-saving, cost-effective configuration which unites a plurality of functions is possible.

Finally, the abovementioned problem is solved by a kit for producing an electronic kiosk system having one or more features provided herein that are provided as a kit.

In particular, with the kit is it possible to form an electronic kiosk system such as is described and claimed herein. The kit has a supporting column and at least two, preferably different, input and/or output modules, wherein their mounting position on the supporting column is freely selectable. For example, a supporting column may be one such as described and claimed herein.

### BRIEF DESCRIPTION OF THE DRAWINGS

The invention will now be described in more detail with reference to a plurality of exemplary embodiments, but is not restricted to these exemplary embodiments. Further exemplary embodiments result from the combination of the features of individual claims or of a plurality of claims with one another and/or with individual features or with the plurality of features of the exemplary embodiments.

FIGS. 1-4 show a plurality of views of a first configuration variant of an electronic kiosk system according to the invention, wherein the kiosk system has a single self-service terminal which has two input and/or output modules,

FIGS. 5-8 show a plurality of views of a second configuration variant of an electronic kiosk system according to the invention, wherein the kiosk system has two self-service terminals which are oriented in opposite directions, wherein each self-service terminal has five input and/or output modules, and

FIGS. 9-12 show a plurality of views of a third configuration variant of an electronic kiosk system according to the invention, wherein the kiosk system has four self-service terminals which are oriented partially in opposite directions and partially in the same direction, wherein each self-service terminal has a plurality of input and/or output modules.

### DETAILED DESCRIPTION

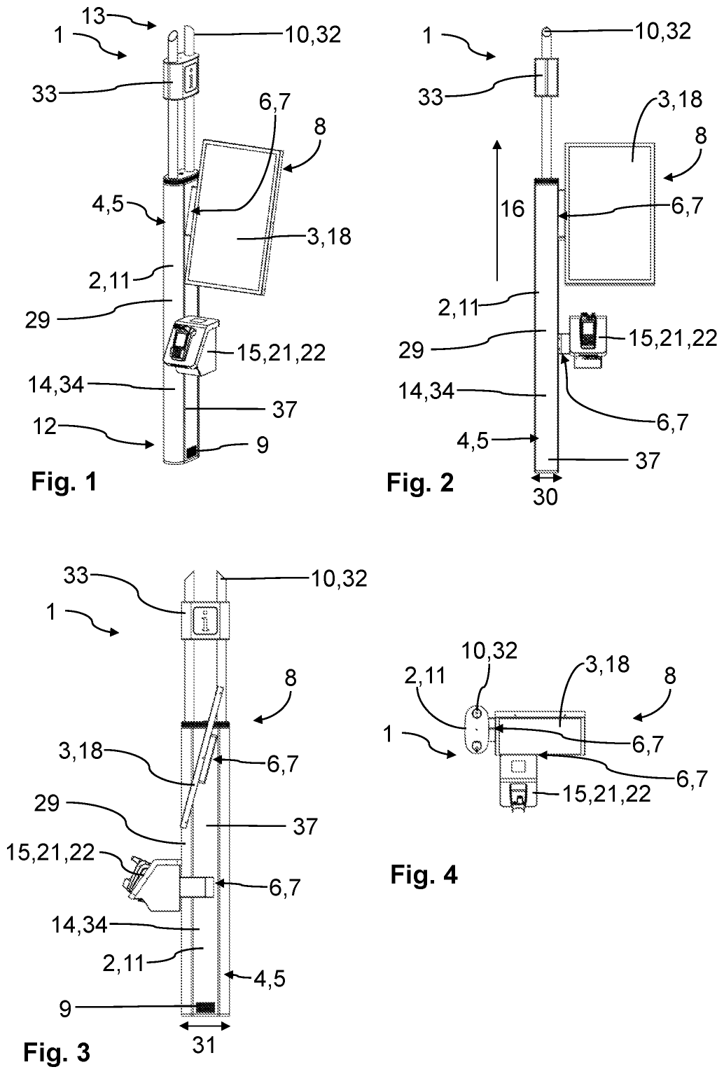

FIGS. 1-12 illustrate a plurality of different embodiment variants of an electronic kiosk system, wherein the electronic kiosk system is denoted in its entirety as 1. The commonalities and differences of the configuration variants are described in more detail below.

The electronic kiosk system 1 has in each case a supporting column 2 which forms the central unit of the kiosk system 1. The supporting column 2 has here a plurality of functions which are described below in detail.

A cross section of the supporting column 2 can have a non-round shape, in particular an oval shape, as can be seen in the plan views in FIGS. 4, 8 and 12.

In the interior of the supporting column 2, at least one storage compartment is formed into which at least one processor unit is inserted via an insertion opening which breaks through a wall 5 of the supporting column 2. Just one processor unit is preferably inserted in each storage compartment. The supporting column therefore functions as a housing 37 for the sensitive components of the kiosk system 1.

The electronic kiosk system 1 also has at least one input and/or output module 3, 15, 36 which is, in particular, connected in a releasable fashion to the supporting column 2 on the outside of the supporting column 2 via a coupling point, so that the at least one input and/or output module 3, 15, 36 is held by the supporting column 2. The supporting column 2 therefore also functions as a stand unit for the at least one input and/or output module 3, 15, 36, in particular for all the input and/or output modules 3, 15, 36 of the kiosk system 1.

The wall 5 of the supporting column 2 has at least, per input and/or output module 3, 15, 36, at least one or precisely one breakthrough 6 via which an interface 7 is formed between the at least one processor unit and the at least one input and/or output module 3, 15, 36. The breakthrough 6 can therefore be formed in a part of the wall 5 which bounds the storage compartment. The interface 7 can be embodied, for example, as a peripheral component interconnect interface (abbreviated as “PCI” interface). In particular, the interface can be configured in such a way that it is possible to replace an input and/or output module 3, 15, 36, connected to the processor unit via said interface, while the processor unit and/or the entire kiosk system 1 is operating (“hot swapping”). However, the interface 7 can also alternatively or additionally be embodied as one or more interfaces selected from USB, FireWire, PCMCIA, SCSI, eSATA and SAS and/or else as a Bluetooth interface.

By use of the interface 7, an electrical coupling is set up between the at least one input and/or output module 3, 15, 36 and the at least one processor unit in the position of use. The processor unit forms, together with the at least one input and/or output module 3, 15, 36, a self-service terminal 8, 17, 38 which can be operated by a user.

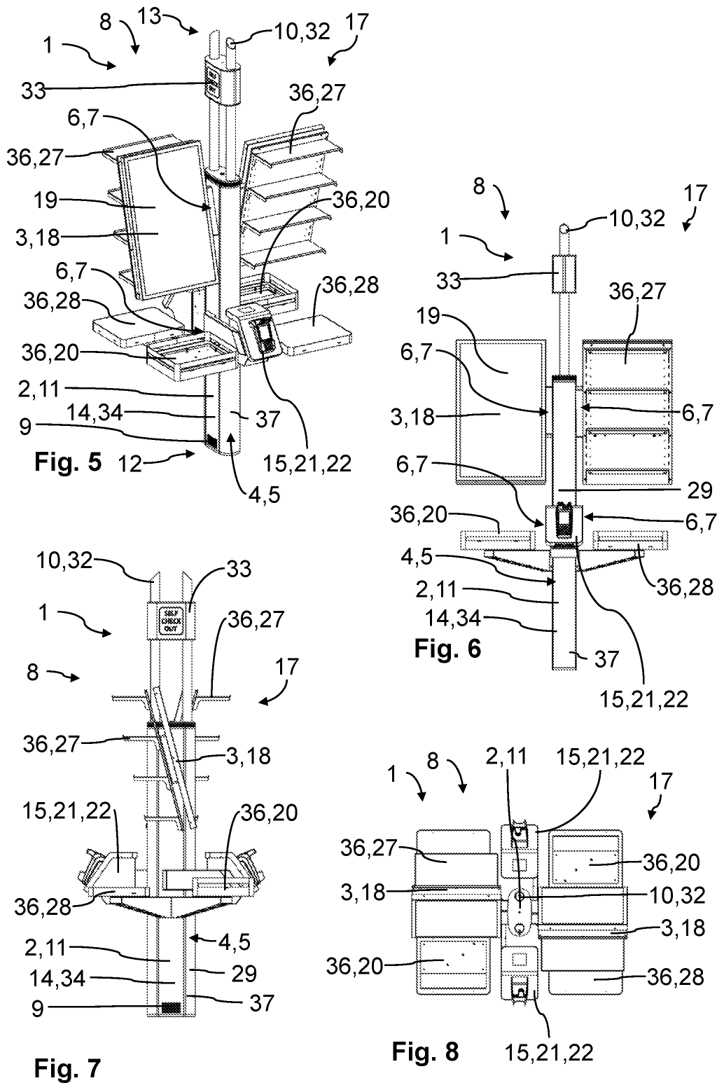

The electronic kiosk system 1 can, however, also have a plurality of self-service terminals 8, 17, 38, as shown, for example, in FIGS. 5-12. Therefore, a plurality of users can use the electronic kiosk system 1 simultaneously.

The kiosk system 1 has one processor unit per self-service terminal 8, 17, 38. This has the advantage that the self-service terminals 8, 17, 38 thereof have comparatively high computing power. Each processor unit can be connected here to a plurality of input and/or output modules 3, 15, 36.

Each processor unit can have at least one local cooler unit which can be embodied, for example, as a cooler/fan combination, ventilator, water cooler and/or passive heat sink. In addition, each processor unit can have at least one processor, RAM memory, BIOS chip, interface module and at least one expansion card.

A central cooler device is arranged on or in the supporting column of the embodiment variants. The central cooler device is configured to suck in cooling air from the outside into the supporting column 2 via an inlet point 9 and to convey it past the at least one processor unit through an air flow duct 11 as far as an outlet point 10. The air flow duct 11 extends here from a first end 12 up to a second end 13 of the supporting column 2. As can be seen in FIGS. 1, 3, 5, 7, 9 and 11, the inlet point 9 can be formed in a foot region at the first lower end 12. The central cooler device can alternatively or additionally to this also be arranged in the foot region of the supporting column 2 and/or in the direct vicinity of the inlet point 9. The inlet point 9 can be formed by a breakthrough 6 or a plurality of breakthroughs 6 in the wall 5 of the supporting column 2. The central cooler device can be embodied, for example, as a flow machine for generating an air flow, such as for example as a blower.

As is illustrated in FIGS. 1-12, the supporting column 2 can be embodied in one piece or can have a single-piece, in particular monolithic, base body. For example, the supporting column 2 or the base body can be configured as a hollow profile 14. One possible way of producing the hollow profile 14 can be extrusion, as a result of which an extruded profile can be produced. The use of a hollow profile 14 and/or an extruded hollow profile has the advantage that its production is particularly cost-effective, the wall 5 is sufficiently solid for it to be able to be used as a stand for relatively heavy components, and an air flow duct 11, which can be used to convey the cooling air, is already formed by the cavity.

As is already shown in FIGS. 1-12, each self-service terminal 8, 17, 38 of the depicted electronic kiosk systems 1 has at least two input and/or output modules 3, 15, 36.

In the embodiment variant in FIGS. 1-4, the kiosk system 1 has just a first self-service terminal 8 which has a first input and/or output module 3 which is embodied as a display 18 and/or touch-sensitive screen (“touchscreen”) 19, and a second input and/or output module 15 which is embodied as a payment module 21 and/or card reader 22.

In the embodiment variant in FIGS. 5-8, the kiosk system 1 has a first self-service terminal 8 and a second self-service terminal 17, wherein each self-service terminal 8, 17 has a first input and/or output module 3 which is embodied as a display 18 and/or touch-sensitive screen (“touchscreen”) 19, a second input and/or output module 15 which is embodied as a payment module 21 and/or card reader 22, a third input and/or output module 36 which is embodied as a balance 20, a fourth input and/or output module 36 which is embodied as a shelf module 27, and a fifth input and/or output module 36 which is embodied as a storage module 28.

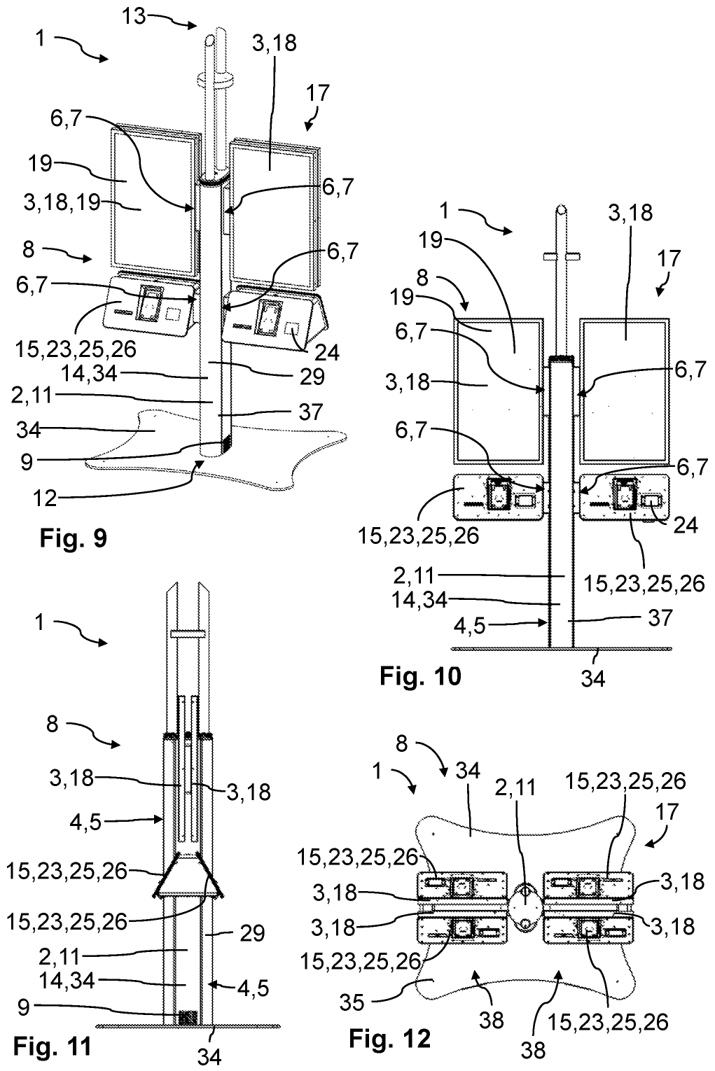

In the embodiment variant in FIGS. 9-12, the kiosk system 1 has a first self-service terminal 8, a second self-service terminal 17 and a third and fourth self-service terminal 38, wherein each self-service terminal 8, 17, 38 has a first input and/or output module 3 which is embodied as a display 18 and/or touch-sensitive screen (“touchscreen”) 19 and second input and/or output module which is embodied as a scanner 23 and/or sensor module 24 and/or printer 25 and/or camera 26. The four self-service terminals 8, 17, 38 are oriented in such a way that in each case two of them are oriented in the same direction and two are oriented in an opposite direction.

However, an angle between the self-service terminals 8, 17, 38 and/or an orientation of the individual self-service terminals 8, 17, 38 is/are basically freely selectable.

A general advantage of the electronic kiosk system 1 is therefore that virtually any desired configuration of the kiosk system 1 is possible by mounting different input and/or output modules 3, 15, 36 on the supporting column 2 so that the kiosk system 1 can be used for a large number of different fields of use. In this context, the input and/or output modules 3, 15, 36 can also be combined in virtually any desired way. For example, the at least one input and/or output module 3, 15, 36 can be embodied as a module or as a plurality of modules selected from the group composed of a display 18, touchscreen 19, balance 20, payment module 21, card reader 22, scanner 23, sensor module 24, printer 25, camera 26, goods output module, goods return module, shelf module 27, storage module 28, wherein this list is not exhaustive.

Therefore, a further aspect of the invention relates to a kit for producing an electronic kiosk system. The kit has at least one supporting column 2 and at least two, preferably differently configured, input and/or output modules 3, 15, 36. By virtue of the freely selectable mounting position on the supporting column 2 it is possible, by using the kit, to produce a large variety of different kiosk systems 1, as have already been described below with respect to the three embodiment variants shown in FIGS. 1-12.

The decision as to where the individual input and/or output modules 3, 15, 36 are attached to the supporting column 2 and what orientation they have is very flexible, since a mounting location is not predefined by the supporting column 2.

The electronic kiosk system 1 has a central supply unit. The central supply unit can supply the at least one processor unit or all the processor units with current during operation. This has the advantage that there is no need for installation space for a plurality of supply units for each processor unit which is provided. Furthermore, a central supply unit produces overall less heat than a plurality of supply units which are respectively assigned to the individual processor units. Therefore, the power of the central cooler device and/or of the local cooler units can be reduced so that the overall current consumption is reduced.

In order to be able to better prevent undesired access to the storage compartment or the storage compartments, the kiosk system 1 can have a cover device 29 which covers and/or closes the latter in the position of use.

A width 30 of the supporting column 2 is determined by the space required by the at least one processor unit. Since the wall 5 bounds the air flow duct 11 at least partially, a width of the air flow duct 11 can be defined by a width of the at least one storage compartment.

The outlet part 10 of the air flow duct 11, which can be formed, for example, by one or more breakthroughs in the wall 5 of the supporting column 2 and/or a tube extension in the longitudinal direction 16 of the supporting column 2, can be capable of being connected or be connected to a ventilation system of a ventilation installation via a connecting line 32. Therefore, the discharge air is transported away and not output into the surrounding space.

The kiosk systems 1 according to the illustrated embodiment variants each have a display and/or lighting device 33. The display and/or lighting device 33 can be controlled here by an, in particular, central display and/or lighting control circuit board.

As is shown in the embodiment variant in FIGS. 9-12, the kiosk system 1 can have a supporting foot 34 of which the footprint is embodied so as to be larger than a cross-sectional area of the supporting column 2. Alternatively or additionally to this, the supporting column 2 and/or the supporting foot 34 can have a securing device 35 by which the entire kiosk system 1 can be attached to the floor. For example, this can be achieved by a screwed connection.

The invention therefore relates, in particular, to an electronic kiosk system 1 comprising at least one supporting column 2 which has a cavity in which at least one storage compartment is formed with an insertion opening, wherein at least one processor unit is inserted into the at least one storage compartment, wherein at least one input and/or output module 3, 15, 36 is arranged on an outer side 4 of a wall 5 of the supporting column 2 and is held by the supporting column 2, wherein the wall 5 of the supporting column 2 has at least one breakthrough 6 which leads from the inside to the outside and by which an interface 7 is formed between the processor unit and the least one input and/or output module 3, 15, 36, as a result of which at least one self-service terminal 8, 17, 38 is formed. In addition, the invention relates to a supporting column 2, to the use of a hollow profile 14 and to a kit for producing an electronic kiosk system 1.

### LIST OF REFERENCE NUMBERS

1 Electronic kiosk system
2 Supporting column
3 First input and/or output module
4 Outer side
5 Wall
6 Breakthrough
7 Interface
8 First self-service terminal
9 Inlet point
10 Outlet point
11 Air flow duct
12 First end
13 Second end
14 Hollow profile
15 Second input and/or output module
16 Longitudinal direction
17 Second self-service terminal
18 Display
19 Touchscreen; touch-sensitive screen
20 Balance
21 Payment module
22 Card reader
23 Scanner
24 Sensor module
25 Printer
26 Camera
27 Shelf module
28 Storage module
29 Cover device
30 Width of supporting column
31 Depth of supporting column
32 Connecting line
33 Display and/or lighting device
34 Supporting foot
35 Securing device
36 Further input and/or output module
37 Housing
38 Further self-service terminal

1. An electronic kiosk system (1) comprising:
at least one supporting column (2) including a wall (5) and at least one storage compartment with an insertion opening,
at least one processor unit inserted into the at least one storage compartment,
at least one input and/or output module (3, 15, 36) arranged on an outer side (4) of the wall (5) of the supporting column (2) that is held by the supporting column (2),
at least one breakthrough (6) in the wall (5) of the supporting column (2), the at least one breakthrough (6) leads outward, and
an interface (7) arranged on at least one breakthrough (6) by which the at least one processor unit is electrically coupled to the at least one input and/or output module (3, 15, 36) in order to form at least one self-service terminal (8, 17, 38).

2. The electronic kiosk system (1) as claimed in claim 1, further comprising a central cooler device arranged in the supporting column (2), the central cooler device is configured to suction in cooling air from the outside into the supporting column (2) via an inlet point (9), and provide an air flow via an air flow duct (11), formed by the supporting column (2), past the at least one processor unit to an outlet point (10).

3. The electronic kiosk system (1) as claimed in claim 2, wherein the air flow duct (11) runs from a first end (12) of the supporting column (2) to a second end (13) of the supporting column (2).

4. The electronic kiosk system (1) as claimed in claim 1, wherein the supporting column (2) is embodied in one part at least partially from a hollow profile (14).

5. The electronic kiosk system (1) as claimed in claim 1, wherein the at least input modules and/or output module comprises at least two of the input modules and/or output modules (3, 15, 36) which are arranged offset with respect to one another in at least one of a circumferential direction or longitudinal direction (16) of the supporting column (2), on the outer side (4) of the wall (5), and are secured by the supporting column (2), and a separate one of the breakthroughs (6) and a separate one of the interfaces (7) for connecting to one of the processor units are formed for each of the input modules and/or output modules (3, 15, 36).

6. The electronic kiosk system (1) as claimed in claim 1, wherein the processor unit comprises two or more of the processor units which are arranged in storage compartments that are arranged offset with respect to one another in a longitudinal direction (16) of the supporting column (2), the at least input modules and/or output module comprises at least two of the input modules and/or output modules (3, 15, 36), and each said processor unit is coupled to at least one input and/or output module (3, 15, 36) and forms an independent self-service terminal (8, 17, 38).

7. The electronic kiosk system (1) as claimed in claim 1, wherein the at least one input and/or output module (3, 15, 36) comprises a module or a plurality of modules selected from the group consisting of: a display (18), a touchscreen (19), a balance (20), a payment module (21), a card reader (22), a scanner (23), a sensor module (24), a printer (25), a camera (26), a goods output module, a goods return module, a shelf module (27), or a storage module (28).

8. The electronic kiosk system (1) as claimed in claim 1, wherein the at least one self-service terminal (8, 17) or each said self-service terminal (8, 17) includes the at least one input and/or output module (3, 15, 36) which is embodied as a display (18).

9. The electronic kiosk system (1) as claimed in claim 1, wherein the electronic kiosk system (1) has a central power supply unit via which the at least one processor unit is adapted to be supplied with current during operation.

10. The electronic kiosk system (1) as claimed in claim 1, wherein the insertion opening of the storage compartment is covered in a position of use by a cover (29).

11. The electronic kiosk system (1) as claimed in claim 1, wherein at least one of a width (30) of the supporting column (2) or a width of an air flow duct formed by the supporting column is determined by at least one of a width of the at least one storage compartment or an envelope space of the at least one processor unit.

12. The electronic kiosk system (1) as claimed in claim 1, wherein the processor unit is formed without a separate power supply unit.

13. The electronic kiosk system (1) as claimed in claim 1, wherein the processor unit is formed with a local cooler unit.

14. The electronic kiosk system (1) as claimed in claim 2, wherein the outlet point (10) of the air flow duct (11) is configured to be connected to a ventilation system of a ventilation installation via a connecting line (32).

15. The electronic kiosk system (1) as claimed in claim 1, further comprising at least one of a display or lighting device (33).

16. The electronic kiosk system (1) as claimed in claim 1, further comprising a supporting foot (34) having a footprint that is larger than a cross-sectional area of the supporting column (2).

17. The electronic kiosk system (1) as claimed in claim 1, wherein the electronic kiosk system (1) is configured to be mounted in a positionally fixed fashion on the ground or in a positionally fixed fashion in a position of use by a securing device (35).

18. A supporting column (2) configured for producing an electronic kiosk system (1), the supporting column including a hollow profile (14) as a base body, the hollow profile having a wall (5) that includes at least one insertion opening into a storage compartment in an interior of the base body and at least one breakthrough (6) into the storage compartment for setting up an interface (7), and an air flow duct (11) which is bounded by the wall (5) of the base body is formed in the interior of the base body.

19. A method of providing a kiosk system, the method comprising:
providing a hollow profile (14) for producing a supporting column (2),
accommodating computer components in the hollow profile (14) which acts as a housing (37) for the computer components in order to protect them against external influences,
using the hollow profile as an air flow duct (11) for cooling the computer components and also as a stand element for at least one input and/or output module (3, 15, 36) which is arranged on an outer side of the hollow profile (14).

20. A kit for producing an electronic kiosk system (1) as claimed in claim 1, wherein the kit includes the supporting column (2) and at least two of the input and/or output modules (3, 15, 36), and a mounting position of the at least two of the input and/or output modules (3, 15, 36) on the supporting column (2) is adapted to be freely selected.
